(19) United States
(12) Patent Application Publication
(10) Pub. No.: US 2023/0005815 A1
(43) Pub. Date: Jan. 5, 2023

(54) COOLING DEVICE

(71) Applicant: MITSUBISHI HEAVY INDUSTRIES, LTD., Tokyo (JP)

(72) Inventors: Hiroki MATSUDA, Tokyo (JP); Tsutomu KAWAMIZU, Tokyo (JP)

(21) Appl. No.: 17/851,561

(22) Filed: Jun. 28, 2022

(30) Foreign Application Priority Data
Jun. 30, 2021 (JP) 2021-109147

(51) Int. Cl. H01L 23/473

(52) U.S. Cl. CPC H01L 23/473

(57) ABSTRACT

A cooling device that cools a semiconductor component mounted on a surface of a substrate, and includes a base mounted to a back surface of the substrate and a bottom plate disposed separately from the base. An introduction port that guides a refrigerant from a direction opposite to the back surface is formed at a position corresponding to the semiconductor component in the bottom plate.

### CROSS-REFERENCE TO RELATED APPLICATIONS

This application claims the benefit of priority to Japanese Patent Application Number 2021-109147 filed on Jun. 30, 2021. The entire contents of the above-identified application are hereby incorporated by reference.

### TECHNICAL FIELD

The disclosure relates to a cooling device.

### RELATED ART

As a device for cooling a semiconductor component (chip), for example, a device described in JP 2006-203138 A is known. In the device described in JP 2006-203138 A below, a cooling channel through which coolant flows is formed between a plurality of semiconductor modules. The coolant is guided from one end of the cooling channel in a lateral direction so as to cool the semiconductor modules.

### SUMMARY

When a plurality of semiconductor components are mounted as described above, heats generated by respective semiconductor components are accumulated, and thus the temperature of a central part increases due to the thermal interference between these semiconductor components. Therefore, in the configuration in which the coolant sequentially flows from the one end of the cooling channel in the lateral direction as in JP 2006-203138 A, there is a concern that a cooling effect in the central part may be insufficient.

The disclosure has been made to solve the problem described above, and an object of the disclosure is to provide a cooling device that produces a higher cooling effect.

In order to solve the above-described problem, the cooling device according to the disclosure is a cooling device that cools a semiconductor component mounted on a surface of a substrate, and includes a base mounted to a back surface of the substrate and a bottom plate disposed separately from the base. An introduction port that guides a refrigerant from a direction opposite to the back surface is formed at a position corresponding to the semiconductor component in the bottom plate.

According to the disclosure, a cooling device that produces a higher cooling effect can he provided.

### BRIEF DESCRIPTION OF DRAWINGS

The disclosure will he described with reference to the accompanying drawings, wherein like numbers reference like elements.

FIG. 1 is a cross-sectional view illustrating a configuration of a cooling device and a substrate according to a first embodiment of the disclosure.

FIG. 2 is a plan view of a cooling device according to a second embodiment of the disclosure.

FIG. 3 is a plan view illustrating a modification example of a cooling device according to a second embodiment of the disclosure.

FIG. 4 is a plan view of a cooling device according to a third embodiment of the disclosure.

FIG. 5 is a plan view illustrating a modification example of a cooling device according to a third embodiment of the disclosure.

FIG. 6 is a plan view illustrating another modification example of a cooling device according to a third embodiment of the disclosure.

FIG. 7 is a plan view illustrating a further modification example of a cooling device according to a third embodiment of the disclosure.

FIG. 8 is a plan view illustrating a further different modification example of a cooling device according to a third embodiment of the disclosure.

FIG. 9 is an enlarged view of a main part of a cooling device according to a fourth embodiment of the disclosure.

FIG. 10 is a cross-sectional view illustrating a configuration of a cooling device and a substrate according to a fifth embodiment of the disclosure.

### DESCRIPTION OF EMBODIMENTS

### First Embodiment

Configuration of Substrate and Cooling Device

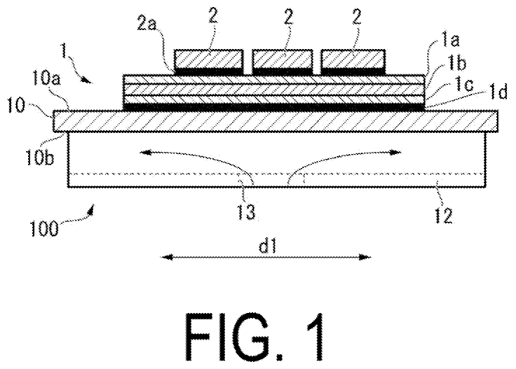

A cooling device 100 according to a first embodiment of the disclosure will be described below with reference to FIG. 1. The cooling device 100 is a device for cooling, by a liquid refrigerant, a semiconductor component 2 mounted on a substrate 1. As illustrated in FIG. 1, the substrate 1 includes copper patterns 1a and 1c, a substrate main body 1b, and bonding materials 2a and 1d.

The substrate main body 1b is formed of, for example, a glass epoxy resin, a Bakelite resin, or the like in a plate shape. The copper patterns 1a and 1c are evaporated on a surface and a back surface of the substrate main body 1b, respectively. A desired printed wiring is formed in the copper patterns 1a and 1c by etching. The bonding material 2a is provided so as to fix the semiconductor component 2 to the copper pattern 1a.

A plurality of (for example, three) semiconductor components 2 are disposed on the substrate 1. The semiconductor component 2 is, for example, a power transistor or a power FET, and generates heat along with the operation thereof. The semiconductor components 2 are disposed on the substrate 1 at intervals from each other. Further, the semiconductor components 2 are electrically connected to the copper pattern 1a described above.

Next, a configuration of the cooling device 100 will be described. As illustrated in FIG. 1, the cooling device 100 includes a base 10 and a bottom plate 12. The base 10 and the bottom plate 12 are integrally formed of a metal material having a good thermal conductivity such as aluminum or copper. It is also possible to form the cooling device 100 by additive manufacturing (AM method).

The base 10 is fixed on the back surface of the substrate 1 described above (that is, a surface facing the opposite side of the surface on which the semiconductor components 2 are mounted) by the bonding material 1d. The base 10 has a plate shape having an area larger than the substrate 1. An introduction port 13 for guiding the refrigerant front the outside is formed in the central part of the bottom plate 12 in a first direction d1 (that is, the central part of a region where the plurality of semiconductor components 2 are disposed). The refrigerant is introduced through the introduction port 13 in a direction from the bottom plate 12 toward the base 10. Note that, in addition to low-temperature water, a long-life coolant (LLC), ethylene glycol, or the like is preferably used as the refrigerant. The refrigerant having flowed from the introduction port 13 flows along the base 10 in two separate directions.

### Operational Effects

Next, an operation of the cooling device 100 will be described. When the semiconductor component 2 is operated, the semiconductor component 2 generates heat due to internal resistance and the like. When the plurality of semiconductor components 2 are disposed in an integrated manner as described above, the temperature becomes high particularly in the central part of an integrated region due to the occurrence of thermal interference. Increase in such heat generation may result in thermal runaway or destruction of the semiconductor components 2. Therefore, in the present embodiment, a configuration is employed in which the semiconductor components 2 are cooled by the cooling device 100.

First, the refrigerant introduced from the introduction port 13 into a channel F changes its orientation by colliding with a back surface 10b of the base 10, and flows toward the end sides of the first direction d1 (the arrows in FIG. 1). During this process, the semiconductor components 2 are cooled by heat absorption by the refrigerant.

According to the configuration described above, the refrigerant can be supplied from the introduction port 13 directly to the central part of the region in which the semiconductor components 2 are integrated. This makes it possible to cool the semiconductor components 2 more efficiently. On the other hand, for example, when the refrigerant flows in one direction from one end to the other end of the channel F, the temperature of the refrigerant increases toward downstream side, and thus there is a possibility that a desired cooling effect cannot be obtained. However, according to the configuration described above, since the introduction port 13 is provided directly below the semiconductor components 2, the above possibility can be reduced, and the low-temperature refrigerant can be always supplied to the semiconductor components 2 on a continuous basis.

The first embodiment of the disclosure has been described above. Note that various changes and modifications can be made to the above-described configurations without departing from the gist of the disclosure.

### Second Embodiment

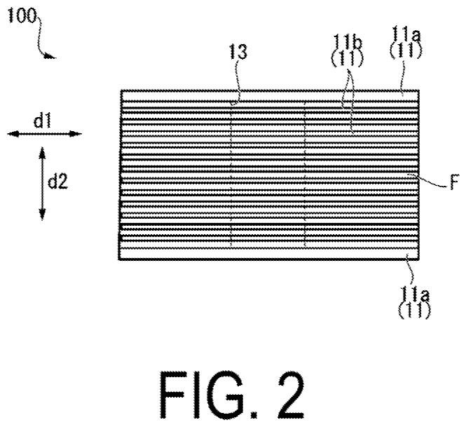

Next, a second embodiment of the disclosure will he described with reference to FIG. 2. Note that the same components as those of the first embodiment will be denoted by the same reference signs, and a detailed description thereof will be omitted. As illustrated in FIG. 2, in the present embodiment, a plurality of fins 11 are provided on the back surface 10b of the base 10. Each of the fins 11 protrudes in a direction away from the base 10. More specifically, the fins 11 extend in the first direction d1 that is a direction along the back surface 10b of the base 10 and are arranged at intervals in a second direction d2 that intersects the first direction d1. Accordingly, the channel F through which the refrigerant flows is formed between the fins 11.

The fin 11 includes an outer fin 11a and an intermediate tin 11b. The outer fin 11a is located on an outermost side in the second direction d2. That is, the outer fin 11a forms an outer shape of the cooling device 100. The outer fin 11a has a plate thickness larger than other fins 11. The outer fin 11a extends over the entire region of the base 10 in the first direction d1.

According to the configuration described above, since the heat dissipation area is increased by the fins 11, the semiconductor components 2 can be more efficiently cooled.

In addition, in the cooling device 100 described above, among a plurality of the fins 11, the fin 11 (the outer fin 11a) located on the outermost side in the second direction d2 has a plate thickness larger than other fins 11.

Here, in the cooling device 100, while the high-pressure refrigerant flows in the channel F, the low-pressure refrigerant after being used for cooling flows outside the outer fins 11a. Thus, a pressure differential occurs between the inside and the outside of the outer fin 11a. According to the configuration described above, since the plate thickness of the outer fin 11a is relatively large, the outer fin 11a can sufficiently withstand the pressure differential that the outer fin 11a receives. Accordingly, a possibility of deformation of the outer fin 11a can he reduced.

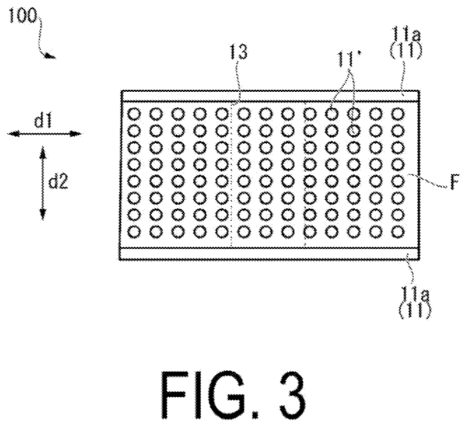

The second embodiment of the disclosure has been described above. Note that various changes and modifications can be made to the above-described configurations without departing from the gist of the disclosure. For example, a pin 11′ can be used instead of the fin 11 described above as illustrated in FIG. 3. A plurality of the pins 11′ protrude from the bottom plate 12 toward the base 10 and are disposed at intervals from each other in the first direction d1 and the second direction d2. With such a configuration, the same effects as those described above can be obtained.

### Third Embodiment

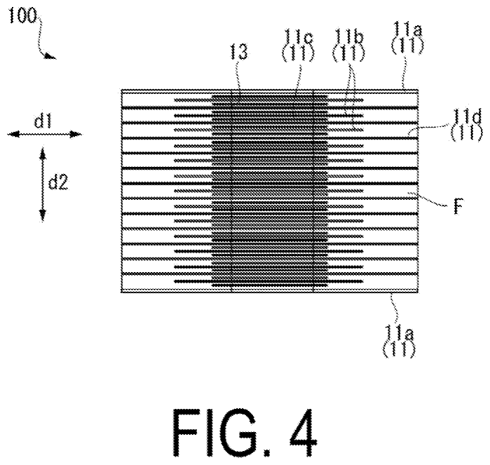

Next, a third embodiment of the disclosure will be described with reference to FIG. 4. The same components as those in each of the above-described embodiments will be denoted by the same reference signs, and a detailed description thereof will be omitted. As illustrated in FIG. 4, in the present embodiment, the fin 11 includes the outer fin 11a, the intermediate fin 11b, a small fin 11c, and a large fin 11d. The outer fin 11a is located on an outermost side in the second direction d2. That is, the outer fin 11a forms an outer shape of the cooling device 100. The outer fin 11a has a plate thickness larger than other tins 11. The outer fin 11a extends over the entire region of the base 10 in the first direction d1.

The large fin 11d is disposed at intervals from the outer fin 11a in the second direction d2. The large fin 11d has a length equivalent to the outer fin 11a in the first direction d1. A pair of intermediate fins 11b and one small fin 11c are arranged between the outer fin 11a and the large fin 11d. The intermediate fin 11b has a dimension smaller than the large fin 11d in the first direction d1, and the small fin 11c has a dimension smaller than the intermediate fin 11b in the first direction d1. The intermediate fin 11b, the small fin 11c, and the large fin 11d are fixed to the base 10 such that the center positions of these fins are identical to each other in the first direction d1. Thus, the width (the dimension in the second direction d2) of the channel F described above gradually increases toward the end sides in the first direction d1. Further, the closer to the center position in the first direction d1, the greater the number of the fins 11 is (the more densely the fins 11 are disposed). A plurality of groups of the fins 11 satisfying the relationship described above is arranged at intervals in the second direction d2.

With the introduction port 13 as a reference, the interval between the fins 11 described above is gradually widened toward the end sides in the first direction d1 away from the introduction port 13.

In the cooling device 100 described above, since the plurality of fins 11 extend in the first direction d1 along the base 10 and are arranged at intervals in the second direction d2, the channel F extending in the first direction d1 is formed between the fins 11. Further, the width of the channel F is gradually widened with increasing distance from the introduction port 13 in the first direction d1.

According to the configuration described above, the interval of the channel F between the fins 11 is relatively narrow in the vicinity of the introduction port 13. That is, the fins 11 are relatively close to each other. Thus, a contact area between the fins 11 and the refrigerant is ensured in the vicinity of the introduction port 13 where the semiconductor components 2 are located. As a result, the cooling effect by the refrigerant can be increased in the vicinity of the introduction port 13 where the semiconductor components 2 are located.

Further, in the cooling device 100 described above, the interval between the fins 11 is gradually widened with increasing distance from the introduction port 13.

According to the configuration described above, it is possible to change the width of the channel F only by changing the interval between the fins 11. This makes it possible to configure the device more easily and inexpensively.

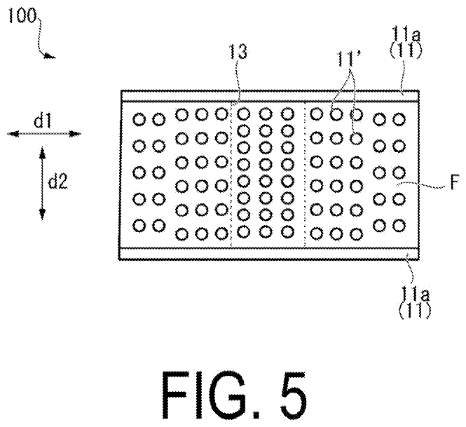

The third embodiment of the disclosure has been described above. Note that various changes and modifications can be made to the above-described configurations without departing from the gist of the disclosure. For example, the pin 11′ can be used instead of the fin 11 described above. As illustrated in FIG. 5, the width of the channel F is gradually widened with increasing distance from the introduction port 13 in the first direction d1.

According to the configuration described above, the interval of the channel F between the pins 11′ is relatively narrow in the vicinity of the introduction port 13. That is, the pins 11′ are relatively close to each other. Thus, a contact area between the pins 11′ and the refrigerant is ensured. As a result, the cooling effect by the refrigerant can be increased in the vicinity of the introduction port 13 where the semiconductor components 2 are located.

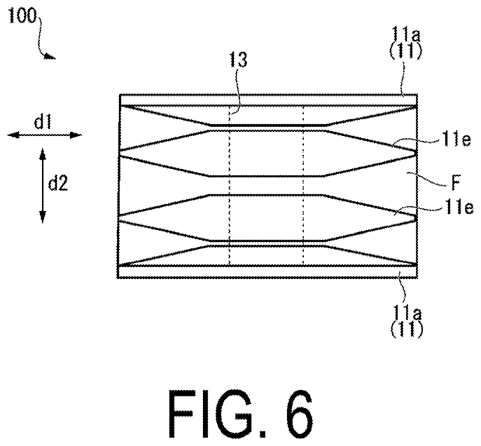

Further, as illustrated in FIG. 6, it is also possible to employ a configuration in which the plate thickness of a fin 11e is gradually decreased from the introduction port 13 toward the end sides in the first direction d1. With such a configuration, the width of the channel F can be changed, and the same effects as those described above can he obtained.

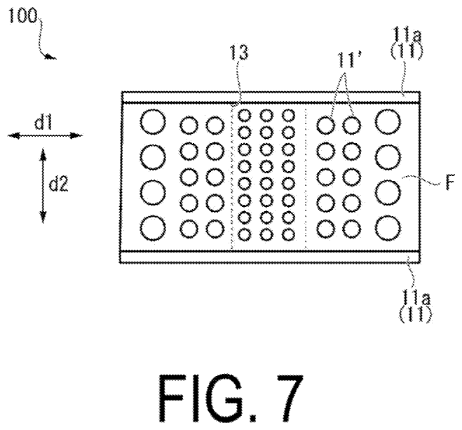

Also, as illustrated in FIG. 7, it is also possible to employ a configuration in which the dimension of the pin 11′ in the second direction d2 is gradually increased and the number of the pins 11′ per unit area is gradually decreased with increasing distance from the introduction port 13.

According to the configuration described above, it is possible to change the width of the channel F only by changing the dimension of the pin 11′ and the number (density) of the pins 11′ per unit area. This makes it possible to configure the device more easily and inexpensively.

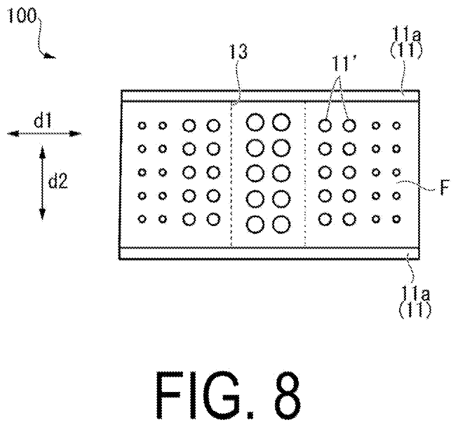

In addition, a configuration illustrated in FIG. 8 can be also employed. In the example illustrated in FIG. 8, the dimension of the pin 11′ in the second direction d2 is gradually decreased with increasing distance from the introduction port 13. Accordingly, the interval between the pins 11′ gradually widened with increasing distance from the introduction port 13.

According to the configuration described above, it is possible to change the width of the channel F only by changing the dimension of the pin 11′ and the interval between the pins 11′. This makes it possible to configure the device more easily and inexpensively.

### Fourth Embodiment

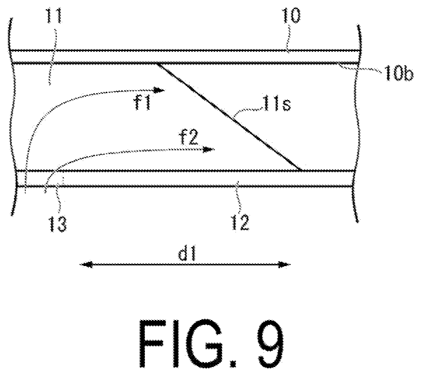

Next, a fourth embodiment of the disclosure will be described with reference to FIG. 9. The same components as those in each of the above-described embodiments will be denoted by the same reference signs, and a detailed description thereof will he omitted. As illustrated in FIG. 9, in the present embodiment, an inclined part 11s is formed at both ends of the fin 11. The inclined part 11s is inclined so as to be gradually separated from the back surface 10b of the base 10 toward the end sides in the first direction d1.

According to the configuration described above, since the inclined part 11s is formed, it is possible to make constant the length of the channel of the refrigerant guided from the introduction port 13 over the entire region in a height direction of the fin 11, as indicated by the arrows in FIG. 9. More specifically, the length of the channel of a refrigerant component (arrow f1) flowing on a side close to the back surface 10b from the introduction port 13 and the length of the channel of a refrigerant component (arrow f2) flowing on a side away from the back surface 10b from the introduction port 13 can be made equal to each other. Accordingly, the flow rate of the refrigerant is made uniform over the entire region of the fins 11, and the cooling effect by the fins 11 can be further increased.

The fourth embodiment of the disclosure has been described above. Note that various changes and modifications can be made to the above-described configurations without departing front the gist of the disclosure.

### Fifth Embodiment

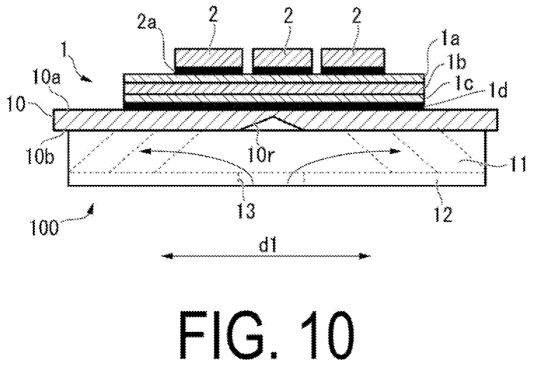

Next, a fifth embodiment of the disclosure will be described with reference to FIG. 10. The same components as those in each of the above-described embodiments will be denoted by the same reference signs, and a detailed description thereof will be omitted. As illustrated in FIG. 10, in the present embodiment, a recessed part 10r that is recessed toward a side of a surface 10a is formed in a central part of the back surface 10b of the base 10 (that is, a central part of a region where the plurality of semiconductor components 2 are disposed). In other words, the plate thickness of the base 10 in the region where the recessed part 10r is formed is smaller than that in other regions. In addition, the cross-sectional shape of the recessed part 10r is triangular, for an example. The recessed part 10r may have a rectangular cross section or an arc cross-section.

According to the configuration described above, since the recessed part is formed in a region facing the introduction port 13 where the semiconductor component 2 is located, the thermal resistance of the base 10 in the region can be made smaller than that in other regions. This facilitates the heat absorption effect of the refrigerant for the semiconductor component 2, and thus the semiconductor component 2 can be cooled more efficiently.

The fifth embodiment of the disclosure has been described above. Note that various changes and modifications can be made to the above-described configurations without departing from the gist of the disclosure. For example, in the fifth embodiment described above, an example in which the recessed part 10r is formed below the central part of the plurality of semiconductor components 2 has been described. However, it is also possible to form one recessed part 10r directly below the central part of each of the semiconductor components 2.

In addition, as a matter common to each of the embodiments, the fins 11 or the pins 11′ may be formed integrally with the bottom plate 12 or may be provided as separate members.

### Notes

The cooling device 100 according to each of the embodiments is understood as follows, for example.

(1) A cooling device 100 according to a first aspect is a cooling device 100 configured to cool a semiconductor component 2 mounted on a surface of a substrate 1. The cooling device 100 includes a base 10 mounted on a back surface of the substrate 1 and a bottom plate 12 disposed separately from the base 10. An introduction port 13 configured to guide a refrigerant from a direction opposite to the back surface is formed at a position corresponding to the semiconductor component 2 in the bottom plate 12.

According to the configuration described above, the refrigerant can be supplied from the introduction port 13 directly to the semiconductor component 2. This makes it possible to cool the semiconductor component 2 more efficiently.

(2) A cooling device 100 according to a second aspect includes a plurality of fins 11 provided between the base 10 and the bottom plate 12.

According to the configuration described above, since the heat dissipation area is increased by the fins 11, the semiconductor component 2 can be more efficiently cooled.

(3) In a cooling device 100 according to a third aspect, since the plurality of fins 11 extend in a first direction d1 along the base 10 and are arranged at intervals in a second direction d2 that intersects the first direction d1, a channel F extending in the first direction d1 is formed between the fins 11. A width of the channel F is gradually widened with increasing distance from the introduction port 13 in the first direction d1.

According to the configuration described above, the interval of the channel F between the fins 11 is relatively narrow in the vicinity of the introduction port 13. That is, the fins 11 are relatively close to each other. Thus, a contact area between the fins 11 and the refrigerant is ensured. As a result, the cooling effect by the refrigerant can be increased in the vicinity of the introduction port 13 where the semiconductor component 2 is located.

(4) In a cooling device 100 according to a fourth aspect, an interval between the fins 11 is gradually widened with increasing distance front the introduction port 13.

According to the configuration described above, it is possible to change the width of the channel F only by changing the interval between the fins 11. This makes it possible to configure the device more easily and inexpensively.

(5) In a cooling device 100 according to a fifth aspect, a plate thickness of eat of the fins 11 in the second direction d2 is gradually decreased with increasing distance front the introduction port 13.

According to the configuration described above, it is possible to change the width of the channel F only by changing the plate thickness of the fin 11. This makes it possible to configure the device more easily and inexpensively.

(6) In a cooling device 100 according to a sixth aspect, the fin 11 located on an outermost side in the second direction d2 has a plate thickness larger than rest of the plurality of fins 11.

According to the configuration described above, the fin 11 located on the outermost side can sufficiently withstand a pressure differential that the fin 11 receives. Accordingly, a possibility of deformation of the fin 11 can be reduced.

(7) In a cooling device 100 according to a seventh aspect, both ends of at least some of the plurality of fins 11 in the first direction d1 are inclined and thus extend toward the end sides in the first direction d1 with increasing distance from the back surface.

According to the configuration described above, since both ends of the fins are inclined, it is possible to make constant the length of the channel of the refrigerant guided from the introduction port 13 over the entire region in a height direction of the fin 11. Accordingly, the flow rate of the refrigerant is made uniform over the entire region of the fins 11, and the cooling effect by the fins 11 can be further increased.

(8) A cooling device 100 according to an eighth aspect includes a plurality of pins 11′ provided between the base 10 and the bottom plate 12.

According to the configuration described above, since the heat dissipation area is increased by the pins 11′, the semiconductor component 2 can be more efficiently cooled.

(9) In a cooling device 100 according to a ninth aspect, since the plurality of pins 11′ are arranged in the first direction d1 along the base 10 and are arranged at intervals in the second direction d2 that intersects the first direction d1, a channel F extending in the first direction d1 is formed between the pins 11′. A width of the channel F is gradually widened with increasing distance from the introduction port 13 in the first direction.

According to the configuration described above, the interval of the channel F between the pins 11′ is relatively narrow in the vicinity of the introduction port 13. That is, the pins 11′ are relatively close to each other. Thus, a contact area between the pins 11′ and the refrigerant is ensured. As a result, the cooling effect by the refrigerant can be increased in the vicinity of the introduction port 13 where the semiconductor component 2 is located.

(10) In a cooling device 100 according to a tenth aspect, an interval between the pins 11′ is gradually widened with increasing distance from the introduction port 13.

According to the configuration described above, it is possible to change the width of the channel F only by changing the interval between the pins 11′. This makes it possible to configure the device more easily and inexpensively.

(11) In a cooling device 100 according to an eleventh aspect, a dimension of each of the pins 11′ in the second direction d2 is gradually decreased with increasing distance from the introduction port 13.

According to the configuration described above, it is possible to change the width of the channel F only by changing the dimension of the pin 11′. This makes it possible to configure the device more easily and inexpensively.

(12) In a cooling device 100 according to a twelfth aspect, a dimension of each of the pins 11′ in the second direction d2 is gradually increased and a number of the pins 11′ per unit area is gradually decreased with increasing distance from the introduction port 13.

According to the configuration described above, it is possible to change the width of the channel F only by changing the dimension of the pin 11′ and the number (density) of the pins 11′ per unit area. This makes it possible to configure the device more easily and inexpensively.

(13) In a cooling device 100 according to a thirteenth aspect, a recessed part 10r that is recessed toward a direction away from the introduction port 13 is formed in a region facing the introduction port 13 in the base 10.

According to the configuration described above, since the recessed part 10r is formed in the region facing the introduction port 13 where the semiconductor component 2 is located, the thermal resistance of the base 10 in the region can be reduced. This makes it possible to cool the semiconductor component 2 more efficiently.

While preferred embodiments of the invention have been described as above, it is to be understood that variations and modifications will be apparent to those skilled in the art without departing from the scope and spirit of the invention. The scope of the invention, therefore, is to be determined solely by the following claims.

1. A cooling device configured to cool a semiconductor component mounted on a surface of a substrate, the cooling device comprising:
a base mounted on a back surface of the substrate; and
a bottom plate disposed separately from the base,
an introduction port being formed at a position corresponding to the semiconductor component in the bottom plate, the introduction port being configured to guide a refrigerant from a direction opposite to the back surface.

2. The cooling device according to claim 1, further comprising a plurality of fins provided between the base and the bottom plate.

3. The cooling device according to claim 2, wherein
the plurality of fins extend in a first direction along the base and are arranged at intervals in a second direction intersecting the first direction,
a channel extending in the first direction is formed between the fins, and
a width of the channel is gradually widened with increasing distance from the introduction port in the first direction.

4. The cooling device according to claim 2, wherein an interval between the fins is gradually widened with increasing distance from the introduction port.

5. The cooling device according to claim 2, wherein a plate thickness of each of the fins in the second direction is gradually decreased with increasing distance from the introduction port.

6. The cooling device according to claim 2, wherein the fin located on an outermost side in the second direction has a plate thickness larger than rest of the plurality of fins.

7. The cooling device according to claim 2, wherein both ends of at least some of the plurality of fins in the first direction are inclined and thus extend toward the end sides in the first direction with increasing distance from the back surface.

8. The cooling device according to claim 1, further comprising a plurality of pins provided between the base and the bottom plate.

9. The cooling device according to claim 8, wherein
the plurality of pins are arranged in a first direction along the base and arranged at intervals in a second direction intersecting the first direction,
a channel extending in the first direction is formed between the pins, and
a width of the channel is gradually widened with increasing distance from the introduction port in the first direction.

10. The cooling device according to claim 8, wherein an interval between the pins is gradually widened with increasing distance from the introduction port.

11. The cooling device according to claim 8, wherein a dimension of each of the pins in the second direction is gradually decreased with increasing distance from the introduction port.

12. The cooling device according to claim 8, wherein a dimension of each of the pins in the second direction is gradually increased and a number of the pins per unit area is gradually decreased with increasing distance from the introduction port.

13. The cooling device according to claim 1, wherein a recessed part that is recessed toward a direction away from the introduction port is formed in a region facing the introduction port in the base.
